(19) United States
(12) Patent Application Publication
(10) Pub. No.: US 2009/0194878 A1
(43) Pub. Date: Aug. 6, 2009

(54) SEMICONDUCTOR DEVICE AND METHOD FOR MANUFACTURING THE SAME

(75) Inventor: Kyu Tae KIM, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,799

(22) Filed: Jun. 27, 2008

(30) Foreign Application Priority Data
Jan. 31, 2008 (KR) 10-2008-0010118

(51) Int. Cl. H01L 23/48; H01L 21/4763

(52) U.S. Cl. 257/758; 438/637; 257/E23.01; 257/E21.495

(57) ABSTRACT

The present invention relates to a semiconductor device and a method of manufacture thereof, particularly, to the technology capable of preventing the overlap failure between the metal line and the bit line pad, since the size of the bit line pad can be increased and the height between the bit line pad and the metal line can be reduced, by designing the semiconductor device to form the bit line and the bit line pad with the stacking structure

### CROSS-REFERENCES TO RELATED APPLICATIONS

The priority of Korean patent application number 10-2008-0010118, filed on Jan. 31, 2008, which is incorporated by reference in its entirety, is claimed.

### BACKGROUND OF THE INVENTION

The present invention relates to a semiconductor device, and more particularly, to a semiconductor device including a bit line and a bit line pad and a manufacturing method thereof.

As the semiconductor device has become highly integrated, more devices have to be formed on a fixed area at high density. The size of an element such as a transistor, a bit line and a capacitor has been gradually decreased due to the high integration of the semiconductor device. Particularly, as the design rule has been reduced in the memory device like the DRAM (Dynamic random access memory), the size of the semiconductor device has been gradually decreased.

In this way, as the size of the semiconductor device has been shrunk, the size of the bit line and the bit line pad has also been decreased proportionally. Generally, the bit line means a conducting wire which is used as a path in which data are moved when storing data in a cell or outputting data stored in a cell. The bit line pad means a contact pad for supplying the power to the core region or the peripheral region. At this time, the bit line pad is formed with the same material and at the same height as the bit line.

Recently, in order to secure enough storage capacitance, the height of a capacitor has increased. Therefore, the location of the metal line has gradually been raised. That is, as the width of capacitor is shrunk, the height increases in order to secure the electrostatic capacity. Accordingly, the location of the metal line is raised. As the location of the metal line gets higher, the height between the metal line and the bit line pad also increases.

Like this, when the height of the metal line and the bit line pad increases, the probability that the metal line contact hole connecting the metal line and the bit line pad deviates from the bit line pad is increased, due to the shortage of the process margin although the alignment between the metal line and the bit line pad coincides. For preventing this, a method that increases the size of the bit line pad is suggested. However, when the size of the bit line pad is increased, a bridge phenomenon between the bit line and the bit line pad can be generated when forming a metal line contact plug.

FIG. 1 is a layout of a semiconductor device according to the related art. The semiconductor device includes a bit line region 112 and a bit line pad region 114. At this time, the bit line pad region 114 is positioned between the bit line regions 112. In conclusion, the size CD of the bit line pad region 114 is determined according to the size between two adjacent bit line regions 112.

Therefore, when the size between two adjacent bit line regions 112 shrinks as the size of the semiconductor device becomes smaller due to the high integration, the size of the bit line pad region 114 should also become smaller. Hence, the align margin of the subsequent metal line is reduced.

FIG. 2 is a cross-sectional view taken along I-I′ of FIG. 1.

The semiconductor device includes a semiconductor substrate 210, a bit line 212, a bit line pad 214 and a metal line contact plug 216. The semiconductor substrate 210 includes the lower portion structure including a gate (not shown) and a landing plug (not shown). The bit line 212 is formed over the semiconductor substrate 210, electrically connected to the landing plug. The bit line pad 214 is formed over the semiconductor substrate 210, electrically connected to the semiconductor substrate 210 or the gate of the lower portion. In addition, the bit line pad 214 is formed between two adjacent bit lines 212. The metal line contact plug 216 is formed by filling up the metal line contact hole with the conductive layer so that the metal line (not shown) and the bit line pad 214 are electrically connected.

However, if the size of the semiconductor device is decreased, the size of the bit line pad 214 is also decreased. Hence, in the case a misalignment is generated from forming the metal line contact plug 216, the bottom gate and the bit line pad 214 can be short-circuited. Moreover, the bottom gate and the bit line pad 214 can be short-circuited due to the shortage of the process margin even if the alignment of the metal line and the bit line pad 214 coincides. As a result, if the gate and bit line pad 214 are short-circuited, the reliability of the semiconductor device is reduced.

### BRIEF SUMMARY OF THE INVENTION

Embodiments of the present invention relate to a bit line and a bit line pad with a stacked structure, so that the size of the bit line pad can be increased and the height between the bit line pad and the metal line can be reduced, thereby, preventing the overlap failure between the metal line and the bit line pad. Furthermore, the present invention can reduce the parasite capacitance (hereinafter, Cb) between the bit lines by increasing the space between the bit lines.

According to an embodiment of the present invention, a semiconductor device includes a bit line; and a bit line pad formed in a layer different from the bit line.

The semiconductor device according to an embodiment of the present invention further includes an interlayer insulating layer formed between the bit line and the bit line pad. The bit line pad is formed on the interlayer insulating layer. The bit line pad is electrically connected to a metal line formed over the bit line pad. The bit line pad has a width which is larger than a distance between two adjacent bit lines. The bit line pad is formed on a core region or a peripheral region.

According to an embodiment of the present invention, a method of manufacturing a semiconductor device includes forming a bit line over a semiconductor substrate; and forming a bit line pad over the bit line.

The forming a bit line includes forming a first interlayer insulating layer on a semiconductor substrate; forming a bit line contact hole structure by selectively etching the first interlayer insulating layer; and forming a first conductive layer in the bit line contact hole structure. The forming a bit line contact hole structure includes forming a bit line via hole which exposes a landing plug by selectively etching a part of the first interlayer insulating layer; and forming a damascene structure connected to the bit line via hole by selectively etching the first interlayer insulating layer. The first conductive layer is formed with the stacking structure of a first barrier metal layer and a first metal layer. The first metal layer includes a tungsten layer. The forming a bit line pad includes forming a second interlayer insulating layer on the bit line and the first interlayer insulating layer; forming a second conductive layer on the second interlayer insulating layer; and patterning the second conductive layer by using a bit line pad mask. The forming a second conductive layer includes forming a bit line pad contact hole by selectively etching the second interlayer insulating layer and the first interlayer insulating layer, and forming the second conductive layer on the second interlayer insulating layer so that the bit line pad contact hole be filled. The bit line pad contact hole exposes the semiconductor substrate or a gate electrode. The second interlayer insulating layer includes one of the nitride film, the oxide film and combinations thereof. The second conductive layer is formed with the stacking structure of a second barrier metal layer and a second metal layer. The second metal layer includes a tungsten layer.

A method of manufacturing a semiconductor device according to an embodiment of the present invention further includes forming a third interlayer insulating layer on the bit line pad and the second interlayer insulating layer; forming a metal line contact plug connected to the bit line pad by selectively etching the third interlayer insulating layer; and forming a metal line on the metal line contact plug.

### BRIEF DESCRIPTION OF THE DRAWINGS

FIG. 1 is a layout of a semiconductor device according to the related art.

FIG. 2 is a cross-sectional view of a semiconductor device according to the related art.

FIG. 3 is a layout of the semiconductor device according to an embodiment of the present invention.

FIG. 4 is a cross-sectional view of a semiconductor device according to an embodiment of the present invention.

FIGS. 5a to 5f are cross-sectional views showing the manufacturing method of a semiconductor device according to an embodiment of the present invention.

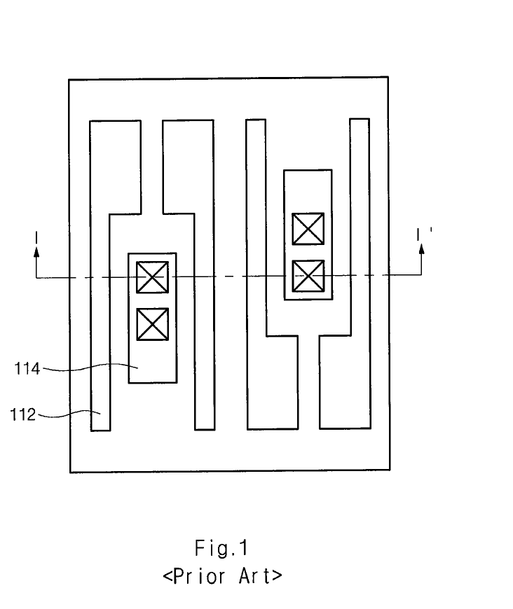

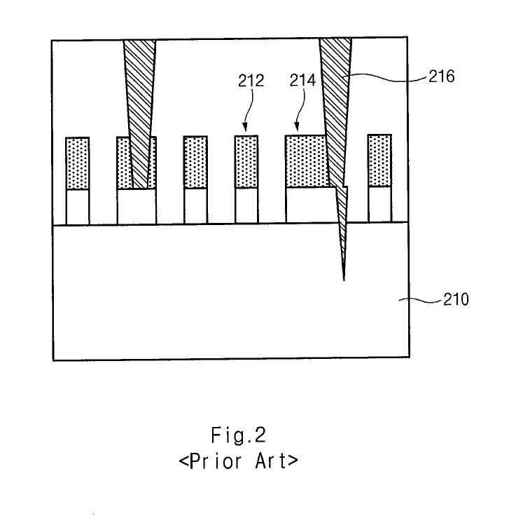

### DESCRIPTION OF EMBODIMENTS

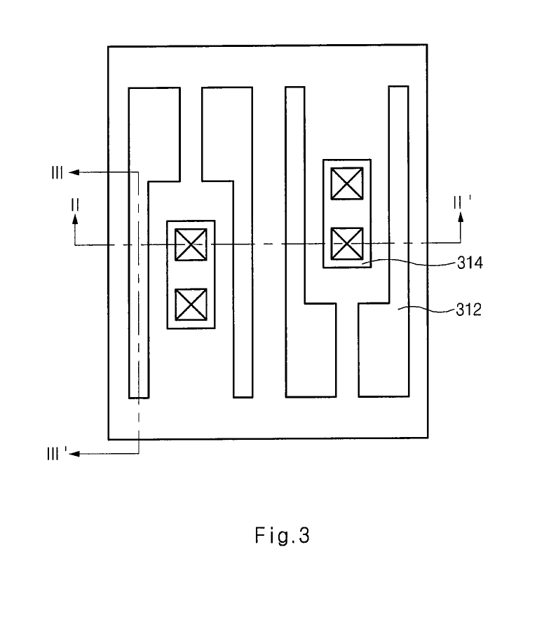

FIG. 3 is a layout of the semiconductor device according to an embodiment of the present invention.

The semiconductor device includes a bit line region 312 and a bit line pad region 314. At this time, the bit line region 312 and the bit line pad region 314 are formed with the stacked structure. That is, the bit line and the bit line pad are formed in a different layer. Therefore, the size (width) of the bit line pad region 314 is not limited by the distance between two adjacent bit line regions 312.

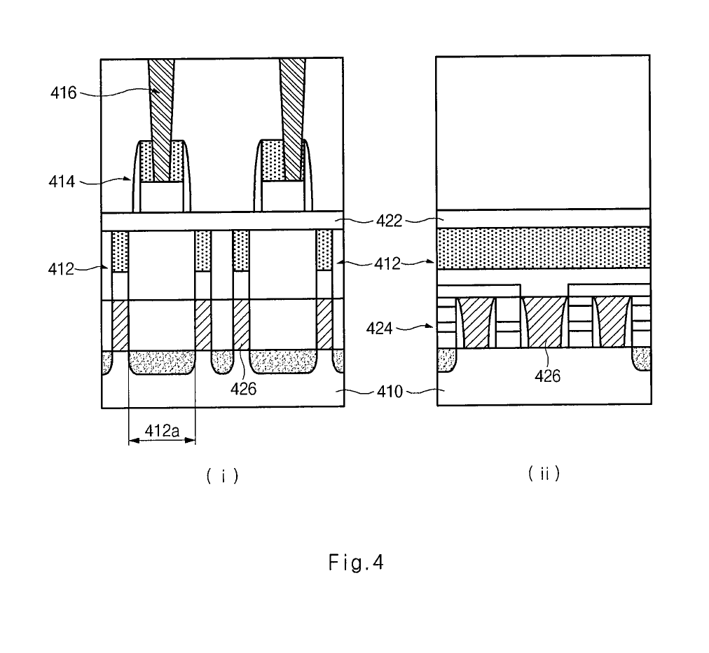

FIG. 4 is a cross-sectional view of a semiconductor device according to an embodiment of the present invention. FIG. 4(i) is a cross-sectional view taken along II-II′ of FIG. 3. FIG. 4(ii) is a cross-sectional view taken along III-III′ of FIG. 3.

The semiconductor device includes a semiconductor substrate 410, a bit line 412 and a metal line contact plug 416. The semiconductor substrate 410 includes the lower portion structure including a gate 424, and a landing plug 426. At this time, the bit line 412 and the bit line pad 414 are formed with the stacked structure.

The bit line 412 is formed over the semiconductor substrate 410 including the lower portion structure, electrically connected to the landing plug 426 of the cell region. The bit line pad 414 is formed over the bit line 412, and electrically connected to the semiconductor substrate 410 or the bottom gate (not shown) of the core region or the peripheral region. The bit line pad 414 is electrically connected to the metal line (not shown) through the metal line contact plug 416. At this time, the bit line 412 and the bit line pad 414 are isolated by an interlayer insulating layer 422.

In the meantime, the bit line pad 414 is positioned between two adjacent bit lines 412. However, since the bit line 412 and the bit line pad 414 are formed in a different layer with the interlayer insulating layer 422 which is interposed between the bit line 412 and the bit line pad 414, the size of the bit line pad 414 is not limited by a distance 412a between two adjacent bit lines 412.

Therefore, the present invention can secure a large enough size of the bit line pad 414. Further, the space between the bit lines 412 is relatively increased, so that the parasite capacitance Cb between the bit lines 412 is reduced. In the present embodiment, it is illustrated that the bit line pad 414 is formed between two bit lines 412, but it is not limitative.

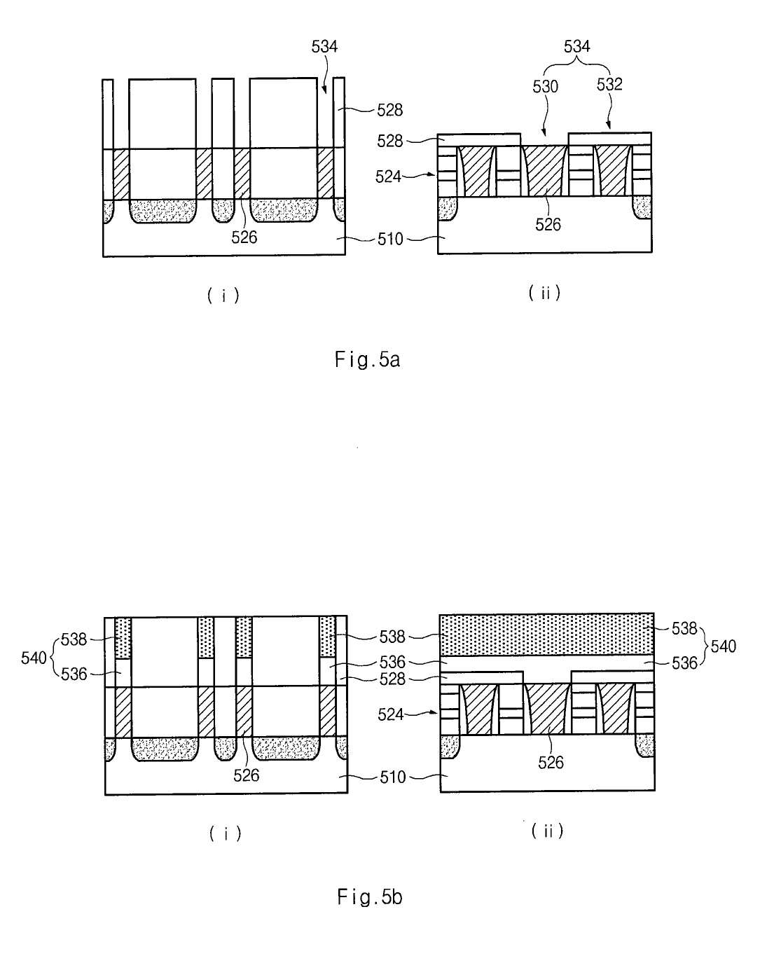

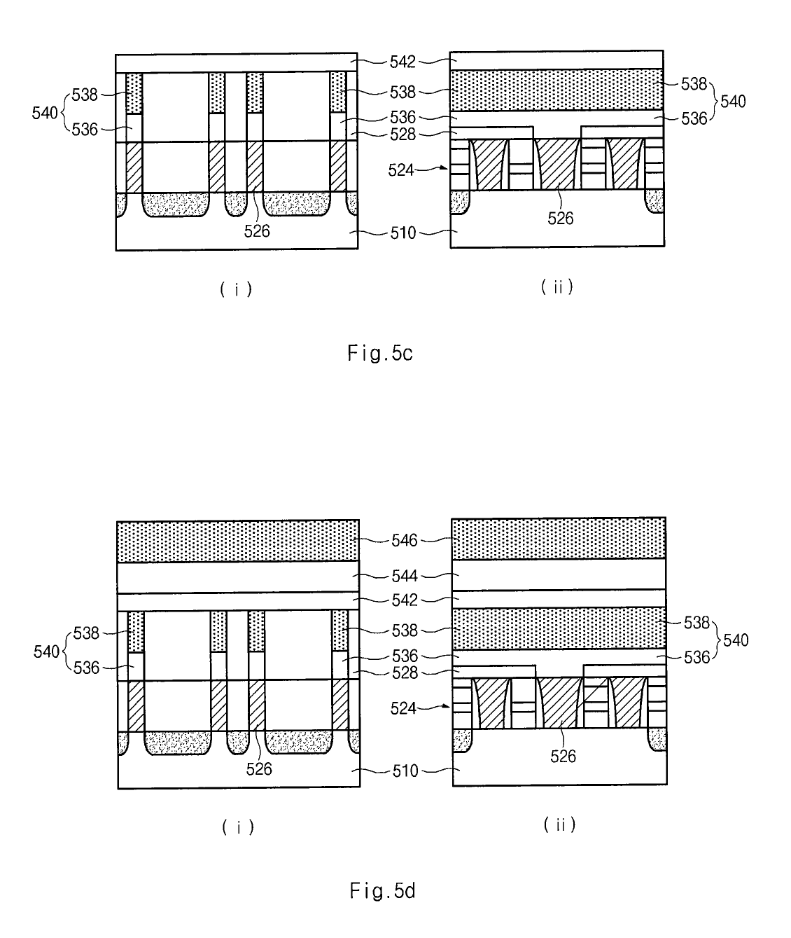

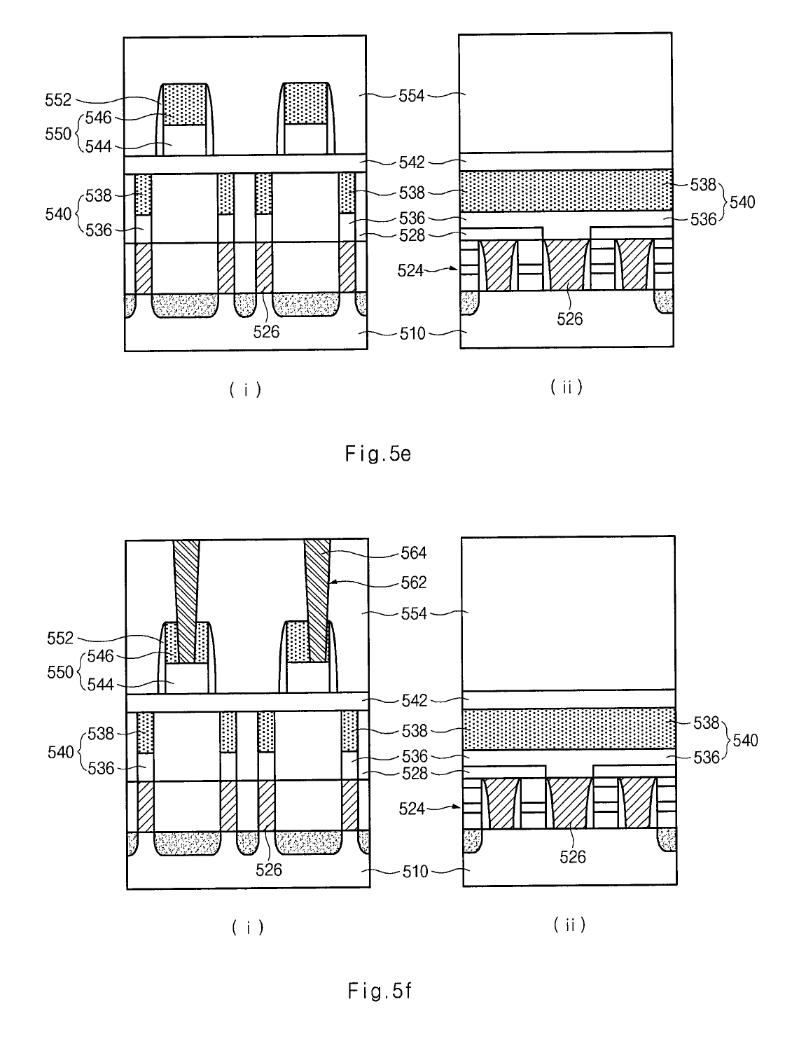

FIGS. 5a to 5f are cross-sectional views showing the manufacturing method of a semiconductor device according to an embodiment of the present invention. In FIGS. 5a to 5f, (i) is cross-sectional views taken along II-II′ of FIG. 3, (ii) is cross-sectional views taken along III-III′ of FIG. 3.

A first interlayer insulating layer 528 is formed on a semiconductor substrate 510 including the lower portion structure such as a gate 524 and a landing plug 526. At this time, the first interlayer insulating layer 528 may be formed with one of the oxide film, the nitride film and combinations thereof. Then, the first interlayer insulating layer 528 is etched by using a bit line contact mask (not shown) until the landing plug 526 is exposed, thereby, a bit line via hole 530 is formed. Thereafter, the first interlayer insulating layer 528 is selectively etched by using a bit line mask (not shown), so that a bit line contact hole structure 534 connected to a bit line via hole 530 is formed. At this time, the bit line contact hole structure 534 may be defined with the bit line via hole 530 and a bit line region 532, formed with the damascene structure.

Referring to FIGS. 5b and 5c, the first conductive layer 536 is formed so that a part of the bit line contact hole structure 534 is filled. At this time, the first conductive layer 536 can be formed so that the bit line via hole 530 is filled. The first conductive layer 536 can be formed with the stacked structure of a first barrier metal layer and a first metal layer. The first barrier metal layer may include one of the titanium layer Ti, the titanium nitride film TiN, the tantalium nitride film TaN, the titanium tungsten layer TiW, the titanium silicide layer TiSix, the tungsten silicide layer WSiX and combinations there of. And the first metal layer may include the tungsten layer W.

Then, a first hard mask layer 538 used as a bit line hard mask layer is formed on the first conductive layer 536 and the first interlayer insulating layer 528. At this time, the first hard mask layer 538 may include the nitride film. Thereafter, the first hard mask layer 538 is planarly etched until the first interlayer insulating layer 528 is exposed, thereby, a bit line 540 is formed. At this time, the planarization etch process for the first hard mask layer 538 may be performed with the chemical mechanical polishing (hereinafter, CMP) method or the etch-back method.

Thereafter, a second interlayer insulating layer 542 is formed on the bit line 540 and the first interlayer insulating layer 528. At this time, the second interlayer insulating layer 542 may include one of the nitride film, the oxide film and combinations t hereof. In conclusion, the bit line 540 is isolated by a layer with the bit line pad 550 shown in FIG. 5e.

Then, the second interlayer insulating layer 542 and the first interlayer insulating layer 528 are selectively etched until the semiconductor substrate 510 or the gate electrode is exposed, so that the bit line pad contact hole (not shown) is formed.

Referring to FIGS. 5d and 5e, a second conductive layer 544 is formed on the second interlayer insulating layer 542 in order for the bit line pad contact hole to be filled, so that the bit line pad contact plug (not shown) is formed. At this time, the second conductive layer 544 may include the stacked structure of the second barrier metal layer and the second metal layer. The second barrier metal layer may include one of the titanium layer Ti, the titanium nitride film TiN, the tantalium nitride film TaN, the titanium tungsten layer TiW, the titanium silicide layer TiSix, the tungsten silicide layer WSiX and combinations thereof. The second metal layer may include the tungsten layer W.

Then, a second hard mask layer 546 used as a bit line pad hard mask layer is formed on the second conductive layer 544. At this time, the second hard mask layer 546 may include the nitride film.

Thereafter, by patterning the second hard mask layer 546 and the second conductive layer 544 through using a bit line pad mask (not shown), a bit line pad 550 which is electrically connected to the bit line pad contact plug is formed.

In the present embodiment, the width of the bit line pad 550 is less than the distance between the adjacent bit lines 540, but it can be implemented with a width greater than this distance.

An insulating layer (not shown) is formed on the bit line pad 550 and the second interlayer insulating layer 542. A spacer 552 is formed in the side wall of the bit line pad 550 by etching the insulating layer.

At this time, the etching process for forming the spacer 552 may be performed with the etch-back method. Further, the spacer 552 may include one of the nitride film, the oxide film and combinations thereof.

A third interlayer insulating layer 554 is formed on the bit line pad 550 including the spacer 552 and the second interlayer insulating layer 542.

Referring to FIG. 5f, the third interlayer insulating layer 554 and the second hard mask layer 546 are selectively etched by using a metal line contact mask (not shown), so that a metal line contact hole 562 which exposes the second metal layer 544 is formed.

Thereafter, a third conductive layer (not shown) is formed so that the metal line contact hole 562 is filled, and the third conductive layer is planarly etched until the third interlayer insulating layer 554 is exposed, thereby, a metal line contact plug 564 is formed.

Then, the metal line electrically connected to the metal line contact plug 564 is formed on the third interlayer insulating layer 554.

As described above, in the present invention, since the bit line pad 550 and the bit line 540 are formed in a different layer, the bit line pad 550 can be formed with a large enough size without being limited by the distance between the bit lines 540.

In addition, as the formation location of the bit line pad 550 gets higher, the gap (height) between the bit line pad 550 and the metal line becomes short, therefore, the length of the metal line contact plug 564 is also decreased. Accordingly, the overlap failure is prevented in forming the metal line contact plug 564.

Further, as the bit line pad 550 is not formed between the bit lines 540, the space between the bit lines 540 relatively increases in comparison with the conventional technology, so that the parasite capacitance Cb is reduced. Accordingly, the reliability of the semiconductor device is improved.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A semiconductor device, comprising:
a bit line; and
a bit line pad formed in a layer different from the bit line.

2. The semiconductor device of claim 1, further comprising an interlayer insulating layer formed between the bit line and the bit line pad.

3. The semiconductor device of claim 2, wherein the bit line pad is formed on the interlayer insulating layer.

4. The semiconductor device of claim 3, wherein the bit line pad is electrically connected to a metal line formed over the bit line pad.

5. The semiconductor device of claim 1, wherein the bit line pad has a width which is larger than a distance between two adjacent bit lines.

6. The semiconductor device of claim 1, wherein the bit line pad is formed on a core region or a peripheral region, or both.

7. A method of manufacturing a semiconductor device, the method comprising:
forming a bit line over a semiconductor substrate; and
forming a bit line pad over the bit line.

8. The method of claim 7, wherein forming a bit line comprises:
forming a first interlayer insulating layer on a semiconductor substrate;
forming a bit line contact hole structure by selectively etching the first interlayer insulating layer; and
forming a first conductive layer in the bit line contact hole structure.

9. The method of claim 8, wherein forming a bit line contact hole structure comprises:
forming a bit line via hole which exposes a landing plug by selectively etching a part of the first interlayer insulating layer; and
forming a damascene structure connected to the bit line via hole by selectively etching the first interlayer insulating layer.

10. The method of claim 8, wherein the first conductive layer is formed with a stacking structure of a first barrier metal layer and a first metal layer.

11. The method of claim 10, wherein the first metal layer includes a tungsten layer.

12. The method of claim 8, wherein forming a bit line pad comprises:
forming a second interlayer insulating layer on the bit line and the first interlayer insulating layer;
forming a second conductive layer on the second interlayer insulating layer; and
patterning the second conductive layer by using a bit line pad mask.

13. The method of claim 12, wherein forming a second conductive layer comprises:
forming a bit line pad contact hole by selectively etching the second interlayer insulating layer and the first interlayer insulating layer; and
forming the second conductive layer on the second interlayer insulating layer so that the bit line pad contact hole is filled.

14. The method of claim 13, wherein the bit line pad contact hole exposes the semiconductor substrate or a gate electrode, or both.

15. The method of claim 12, wherein the second interlayer insulating layer includes the nitride film, the oxide film, or combinations thereof.

16. The method of claim 12, wherein the second conductive layer has a stacking structure including a second barrier metal layer and a second metal layer.

17. The method of claim 16, wherein the second metal layer includes a tungsten layer.

18. The method of claim 7, further comprising:
forming a third interlayer insulating layer on the bit line pad and the second interlayer insulating layer;
forming a metal line contact plug connected to the bit line pad by selectively etching the third interlayer insulating layer; and
forming a metal line on the metal line contact plug.
